(19) United States
(12) Patent Application Publication
(10) Pub. No.: US 2026/0140826 A1
(43) Pub. Date: May 21, 2026

(54) ERROR CORRECTION CIRCUIT AND SEMICONDUCTOR DEVICE INCLUDING SAME

(71) Applicant: SK hynix Inc., Icheon-si Gyeonggi-do (KR)

(72) Inventors: Seon Woo HWANG, Icheon-si Gyeonggi-do (KR); Seong Jin KIM, Icheon-si Gyeonggi-do (KR); Jung Hwan JI, Icheon-si Gyeonggi-do (KR)

(73) Assignee: SK hynix Inc., Icheon-si Gyeonggi-do (KR)

(21) Appl. No.: 19/077,770

(22) Filed: Mar. 12, 2025

(30) Foreign Application Priority Data
Nov. 20, 2024 (KR) 10-2024-0166508

(51) Int. Cl. G06F 11/10; G06F 11/07

(52) U.S. Cl. CPC G06F 11/1068; G06F 11/0781; G06F 11/106

(57) ABSTRACT

An error correction circuit includes an error processing circuit, a poison processing circuit, and a data pattern conversion circuit. The error processing circuit receives data, generates delayed data, a parity signal, and syndrome information, and outputs error correction data generated by correcting errors in the data according to the syndrome information. The poison processing circuit outputs one of a write poison flag and a read poison flag as a poison pattern control signal in accordance with a write command. The data pattern conversion circuit converts the delayed data and the parity signal into a poison pattern according to the poison pattern control signal and outputs the poison pattern.

### CROSS-REFERENCES TO RELATED APPLICATION

The present application claims priority under 35 U.S.C. §119(a) to Korean application number 10-2024-0166508 filed on Nov. 20, 2024, in the Korean Intellectual Property Office, which application is incorporated herein by reference in its entirety.

### BACKGROUND

### 1. Technical Field

The present disclosure generally relates to a semiconductor circuit, including but not limited to error correction circuits and semiconductor devices including error correction circuits.

### 2. Related Art

As the operating speed of semiconductor devices increases, the time specifications for various operations decreases, and the bit error rate increases accordingly. Semiconductor devices perform an Error Correction Code (ECC) function that detects and corrects bit errors. ECC is a function in which the semiconductor device corrects errors in data by adding an ECC check bit to the data.

An Error Check and Scrub (ECS) function and a poison function using output from the ECC function are included in operating standards for semiconductor devices.

The ECS function in semiconductor devices is a feature that increments an address for access to a memory region, reads the stored data, and when an error is detected, corrects and writes the corrected data. The poison function notifies and manages external delivery of poisoned data, for example, data that contains internal errors, rather than errors that occurred during processing of data by semiconductor devices.

### SUMMARY

In an embodiment, an error correction circuit may include an error processing circuit, a poison processing circuit, and a data pattern conversion circuit. The error processing circuit may be configured to receive data, may be configured to generate delayed data, a parity signal, and syndrome information, and may be configured to output error correction data generated by correcting errors in the data according to the syndrome information. The poison processing circuit may be configured to output one of a write poison flag and a read poison flag as a poison pattern control signal in accordance with a write command. The data pattern conversion circuit may be configured to convert the delayed data and the parity signal into a poison pattern according to the poison pattern control signal and output the poison pattern.

In an embodiment, an error correction circuit may include an error processing circuit, a poison processing circuit, and an error severity determination circuit. The error processing circuit may be configured to receive data, may be configured to generate delayed data, a parity signal, and syndrome information and may be configured to output error correction data generated by correcting errors in the data according to the syndrome information. The poison processing circuit may be configured to output a result of detecting whether the data is poisoned as a read poison flag in accordance with a read command. The error severity determination circuit may be configured to store error severity information at a level that facilitates a write operation regardless of the syndrome information when the read poison flag is activated.

In an embodiment, an error correction circuit may include an error processing circuit, a poison processing circuit, a data pattern conversion circuit, an error severity determination circuit, and a command control circuit. The error processing circuit may be configured to receive data, may be configured to generate delayed data, a parity signal, and syndrome information, and may be configured to output error correction data generated by correcting errors in the data according to the syndrome information. The poison processing circuit may be configured to output a result of detecting whether the data is poisoned as a read poison flag according to a read command, and may be configured to output one of a write poison flag and the read poison flag as a poison pattern control signal according to a write command. The data pattern conversion circuit may be configured to convert the delayed data and the parity signal into a poison pattern according to the poison pattern control signal and output the poison pattern. The error severity determination circuit may be configured to store a result of operation on the syndrome information according to a predetermined operation logic as error severity information when the read poison flag is deactivated and may be configured to store the error severity information at a level that facilitates a write operation regardless of the syndrome information when the read poison flag is activated. The command control circuit may be configured to activate the write command in accordance with the error severity information.

In an embodiment, a semiconductor device may include a memory region; a first global line coupled with the memory region and configured to transmit data output from the memory region; a second global line coupled with the memory region and configured to transmit data input from an external source to the memory region; and an error correction circuit coupled with the first global line and the second global line. The error correction circuit may be configured to perform an error processing operation on first data transmitted on the first global line during an error check and scrub read operation to generate error correction data, and when the first data is poisoned data, activate a read poison flag and store error severity information corresponding to the first data at a level facilitating a write operation regardless of the error processing operation; and receive a global line latch signal latched from the first global line during an error check and scrub write operation, and when the read poison flag is activated, convert the global line latch signal into a poison pattern and output the poison pattern on the second global line.

In an embodiment, a method may include receiving data by an error correction circuit; generating syndrome information; outputting error correction data generated by correcting errors in the data according to the syndrome information; outputting one of a write poison flag and a read poison flag as a poison pattern control signal in accordance with a write command; converting delayed data and a parity signal into a poison pattern according to the poison pattern control signal and outputting the poison pattern; and storing error severity information at a level that facilitates a write operation regardless of the syndrome information when the read poison flag is activated.

### BRIEF DESCRIPTION OF THE DRAWINGS

FIG. 1 is a diagram illustrating a configuration of an error correction circuit according to an embodiment of the present disclosure.

FIG. 2A is a diagram illustrating a configuration of an input/output control circuit according to an embodiment of the present disclosure.

FIG. 2B is a table including signals during operation of an input/output control circuit according to an embodiment of the present disclosure.

FIG. 3 is a diagram illustrating a configuration of a poison detection circuit according to an embodiment of the present disclosure.

FIG. 4 is a diagram illustrating a configuration of a poison latch according to an embodiment of the present disclosure.

FIG. 5 is a diagram illustrating a configuration of a data pattern conversion circuit according to an embodiment of the present disclosure.

FIG. 6 is a diagram illustrating a configuration of an error severity determination circuit according to an embodiment of the present disclosure.

FIG. 7 is a diagram illustrating a configuration of a command control circuit according to an embodiment of the present disclosure.

FIG. 8 is a diagram illustrating an error correction circuit during an ECS read operation according to an embodiment of the present disclosure.

FIG. 9 is a diagram illustrating an error correction circuit during an ECS write operation according to an embodiment of the present disclosure.

FIG. 10 is a diagram illustrating a configuration of a semiconductor device according to an embodiment of the present disclosure.

### DETAILED DESCRIPTION

Various embodiments can efficiently detect and correct data errors in semiconductor device by supporting a poison function in ECS operation, as well as supporting ECC and ECS functions.

Various embodiments can support ECC, ECS, and poison functions while minimizing circuit area and power consumption.

Various embodiments store poisoned data in the memory region but do not store additional information to distinguish poisoned data from other data in the memory region. As a result, the available memory capacity is not reduced and management of the poison function is facilitated.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The Error Check and Scrub (ECS) function includes a function that reads stored data and internally increments an address of a semiconductor device when the semiconductor device is not in use, corrects an error when the error is detected, and stores the error-corrected data in the same location from which the data was read. The semiconductor device enters an ECS mode and performs active-read-write-precharge operations during a time period when external access and internally-determined operation are not performed, for example, during a self-refresh operation interval. Optionally, a controller external to the semiconductor device may monitor operation of the semiconductor device and enter the ECS mode during a free or inactive time period. A read operation when entering ECS mode is referred to as an ECS read operation, and an operation including writing data to the same memory region according to the ECS read operation is referred to as an ECS write operation.

The operation specifications of semiconductor device indicate that write operations are prohibited when the information identifying the error severity of data, referred to as error severity information, is at a UE (Uncorrectable Error) level. Error severity may be categorized as NE (No Error), CE (Correctable Error), UE, and so forth.

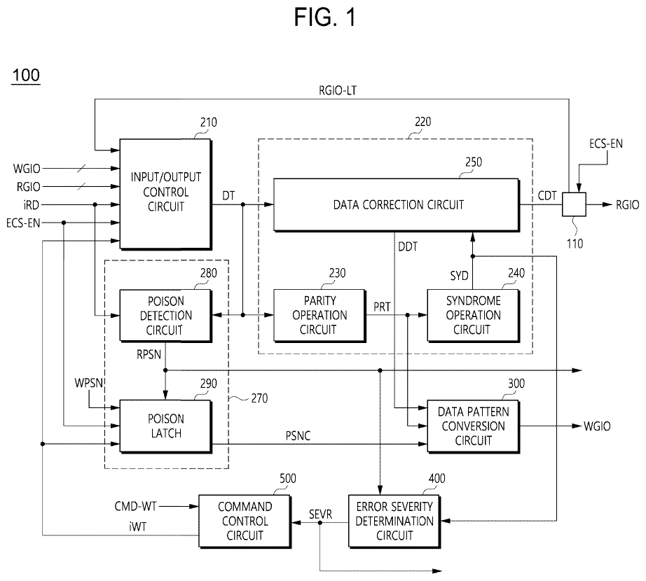

FIG. 1 is a diagram illustrating an error correction circuit 100 according to an embodiment of the present disclosure.

Referring to FIG. 1, the error correction circuit 100 includes a global line latch circuit 110, an input/output control circuit 210, an error processing circuit 220, a poison processing circuit 270, a data pattern conversion circuit 300, an error severity determination circuit 400, and a command control circuit 500.

The global line latch circuit 110 latches error correction data CDT according to an error check and scrub mode enable signal ECS-EN and transmits the error correction data CDT on a first global line RGIO. The global line latch circuit 110 latches and transmits the error correction data CDT on the first global line RGIO upon deactivation of the error check and scrub mode enable signal ECS-EN. The global line latch circuit 110 latches the error correction data CDT when the error check and scrub mode enable signal ECS-EN is enabled and blocks the latched signal from being output outside of the semiconductor device on the first global line RGIO.

The error check and scrub mode enable signal ECS-EN is used as a signal to identify whether the semiconductor device is operating in an ECS mode. The error check and scrub mode enable signal ECS-EN is activated when the semiconductor device is in the ECS mode and deactivated when the semiconductor device is not in the ECS mode. Activation of the error check and scrub mode enable signal ECS-EN indicates that a logic level of the error check and scrub mode enable signal ECS-EN is at a high level, and the deactivation of the error check and scrub mode enable signal ECS-EN indicates that a logic level of the error check and scrub mode enable signal ECS-EN is at a low level. Alternatively, activation of the error check and scrub mode enable signal ECS-EN may indicate a low logic level, and deactivation of the error check and scrub mode enable signal ECS-EN may indicate a high logic level. In an embodiment of the present disclosure, activation occurs when a signal is at a high level and deactivation occurs when a signal is at a low level. In the present disclosure, a signal at a high level indicates activation, and a signal at a low level indicates deactivation.

The input/output control circuit 210 selects one of a signal transmitted on the first global line RGIO, a signal transmitted on a second global line WGIO, and a global line latch signal RGIO-LT latched in the global line latch circuit 110 according to the error check and scrub mode enable signal ECS-EN, a read command iRD, and a write command iWT and outputs the selected signal as data DT.

The read command iRD is generated from a read command input from outside the semiconductor device, referred to as an external read command, for a normal read operation or is generated internally within the semiconductor device independent of the external read command for an ECS read operation. The write command iWT is generated in response to a write command input from outside the semiconductor device, referred to as an external write command, for a normal write operation or is generated internally within the semiconductor device independent of the external write command for an ECS write operation.

The first global line RGIO is used for a read operation of the semiconductor device and includes a plurality of signal lines corresponding to a data width of the semiconductor device. The second global line WGIO is used for a write operation of the semiconductor device and includes a plurality of signal lines corresponding to a data width of the semiconductor device.

The error processing circuit 220 performs error processing operations on the data DT and outputs error correction data CDT generated by correcting errors in the data DT accordingly. The error processing circuit 220 receives the data DT as input and generates delayed data DDT, a parity signal PRT, syndrome information SYD, and error correction data CDT. The error processing operation may be performed based on a block code or a convolution code. The block code may include a Hamming code, a Reed-Solomon (RS) code, and a BCH code, and the convolution code may include a Viterbi code and a Turbo code. The error processing circuit 220 outputs the error correction data CDT generated by correcting errors in the data DT according to the syndrome information SYD.

The error processing circuit 220 includes a parity operation circuit 230, a syndrome operation circuit 240, and a data correction circuit 250.

The parity operation circuit 230 receives the data DT as input and outputs the parity signal PRT. The parity operation circuit 230 performs a parity operation on the input data DT to generate the parity signal PRT.

The syndrome operation circuit 240 receives the parity signal PRT and outputs the syndrome information SYD. The syndrome operation circuit 240 decodes the parity signal PRT to generate the syndrome information SYD.

The data correction circuit 250 receives the data DT and the syndrome information SYD as inputs and outputs the error correction data CDT. The data correction circuit 250 corrects errors in the data DT according to the syndrome information SYD to generate the error correction data CDT. The data correction circuit 250 delays the data DT by a first delay time period to generate the delayed data DDT and corrects errors in the delayed data DDT according to the syndrome information SYD to generate the error correction data CDT. The first delay time period may be adjusted to a time period corresponding to a signal processing time period to generate the parity signal PRT and the syndrome information SYD, for example, a signal processing time period of the parity operation circuit 230 and the syndrome operation circuit 240.

The poison processing circuit 270 receives the data DT, the read command iRD, the write command iWT, the error check and scrub mode enable signal ECS-EN, and a write poison flag WPSN as inputs and outputs a read poison flag RPSN and a poison pattern control signal PSNC. The write poison flag WPSN may be provided by a system external to the semiconductor device. The write poison flag WPSN is a signal that indicates whether the data provided by the system external to the semiconductor device for a normal write operation is poisoned. The data provided as poisoned is referred to as poisoned data. The write poison flag WPSN is at a high level when the data provided for a normal write operation is poisoned data and at a low level when the data is not poisoned data.

The poison processing circuit 270 outputs a result of detecting whether the data DT is poisoned as the read poison flag RPSN according to the read command iRD. The read poison flag RPSN is at a high level when the data DT is poisoned data and at a low level when the data DT is not poisoned data.

The poison processing circuit 270 selects one of the write poison flag WPSN and the read poison flag RPSN according to the error check and scrub mode enable signal ECS-EN and latches the selected signal according to the write command iWT and outputs the selected signal as the poison pattern control signal PSNC.

The data pattern conversion circuit 300 converts the delayed data DDT and the parity signal PRT into a poison pattern according to the poison pattern control signal PSNC and outputs the poison pattern. The data pattern conversion circuit 300 bypasses the delayed data DDT and the parity signal PRT according to a level of the poison pattern control signal PSNC or converts and outputs the delayed data DDT and the parity signal PRT according to a logic level corresponding to the poison pattern regardless of an original value of the delayed data DDT and the parity signal PRT. An output of the data pattern conversion circuit 300 is transmitted on the second global line WGIO.

The error severity determination circuit 400 receives the read poison flag RPSN and the syndrome information SYD as input and outputs error severity information SEVR. The error severity determination circuit 400 stores and outputs a result of a predetermined logic operation on the syndrome information SYD as the error severity information SEVR when the data according to the read operation is not poisoned data, for example, when the read poison flag RPSN is at a low level. The word “predetermined” as used with respect to a parameter, such as a predetermined timing, time, time period, or voltage level, indicates that a value for the parameter is determined prior to use of the parameter in a process or algorithm. In an embodiment, the value of the parameter is determined before the process or algorithm begins. In an embodiment, the value for the parameter is determined during the process or algorithm but before the parameter is used during the process or algorithm. The error severity information SEVR is at a low level when the error severity of the data is at NE or CE level where write operation is possible or at a high level when the error severity is at the UE level when write operation is prohibited. The error severity determination circuit 400 stores the error severity information SEVR at a low level corresponding to NE or CE that facilitates a write operation, regardless of the syndrome information SYD, when the data according to the read operation is poisoned data, for example, when the read poison flag RPSN is at a high level.

The command control circuit 500 receives an external write command CMD-WT and the error severity information SEVR and outputs the write command iWT. The command control circuit 500 causes deactivation of the write command iWT based on the error severity information SEVR. The command control circuit 500 outputs the external write command CMD-WT as the write command iWT when the error severity information SEVR is at a low level and deactivates the write command iWT independently of the external write command CMD-WT when the error severity information SEVR is at a high level.

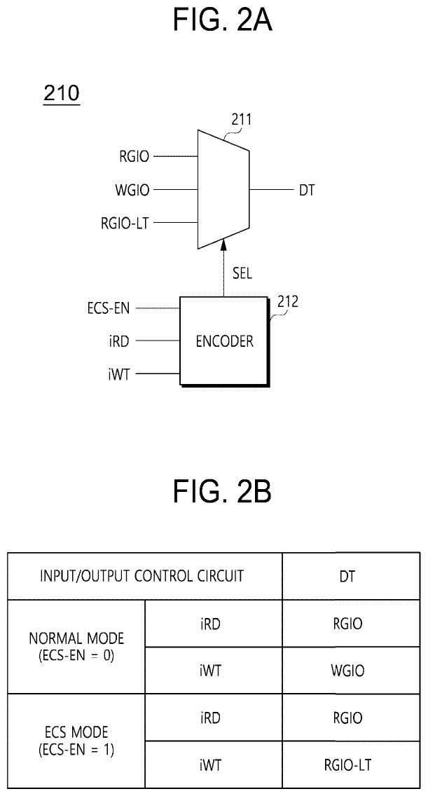

FIG. 2A is a diagram illustrating a configuration and an operation of the input/output control circuit 210, for example, as shown in FIG. 1, and FIG. 2B is a table including signals during operation of the input/output control circuit 210.

Referring to FIG. 2A, the input/output control circuit 210 includes a multiplexer 211 and an encoder 212.

The multiplexer 211 selects one of a signal transmitted on the first global line RGIO, a signal transmitted on the second global line WGIO, and the global line latch signal RGIO-LT based on a selection signal SEL to output as the data DT. The encoder 212 encodes the error check and scrub mode enable signal ECS-EN, the read command iRD, and the write command iWT to generate the selection signal SEL.

The input/output control circuit 210 outputs a signal transmitted on the first global line RGIO as the data DT when the read command iRD is input and outputs a signal transmitted on the second global line WGIO as the data DT when the write command iWT is input in a normal mode, for example, when the error check and scrub mode enable signal ECS-EN is at a low level. The input/output control circuit 210 outputs a signal transmitted on the first global line RGIO as the data DT when the read command iRD is input and outputs the error correction data CDT generated during a previous ECS read operation, for example, the global line latch signal RGIO-LT, as data DT when the write command iWT is input in an ECS mode, for example, when the error check and scrub mode enable signal ECS-EN is at a high level.

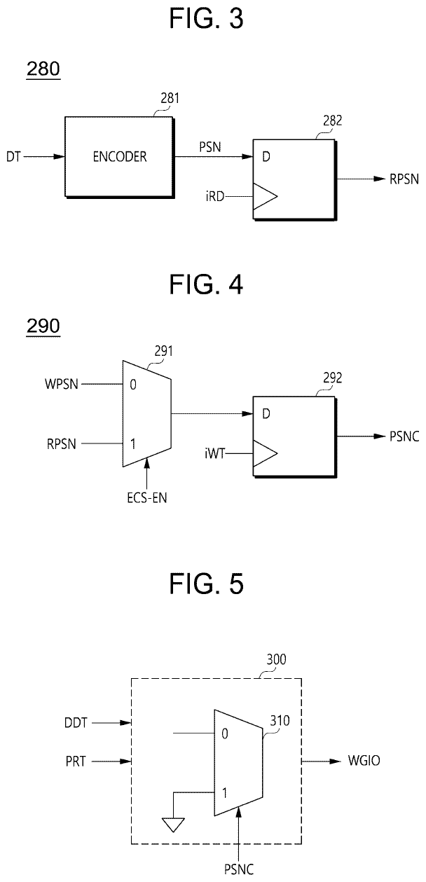

FIG. 3 is a diagram illustrating a configuration of the poison detection circuit 280, for example, as shown in FIG. 1.

Referring to FIG. 3, the poison detection circuit 280 includes an encoder 281 and a flip-flop 282. By encoding the data DT in a prescribed manner, the encoder 281 outputs whether a pattern in the data DT matches a predetermined poison pattern as a poison flag PSN. The poison pattern is a data pattern associated with a high level of the error severity information SEVR corresponding to UE. The poison pattern may include various in a semiconductor device, for example, all data bits may have a value of 0 or all data bits may have a value of 1.

The encoder 281 outputs the poison flag PSN at a predetermined level, such as a high level, when a pattern in the data DT matches a predetermined poison pattern. The encoder 281 outputs the poison flag PSN at a low level when the pattern in the data DT does not match the predetermined poison pattern. The flip-flop 282 outputs a signal that latches the poison flag PSN according to the read command iRD as the read poison flag RPSN. The poison detection circuit 280 outputs the read poison flag RPSN at a high level to indicate externally that the data according to the read command iRD is poisoned data.

FIG. 4 is a diagram illustrating a configuration of the poison latch 290, for example, as shown in FIG. 1.

Referring to FIG. 4, the poison latch 290 includes a multiplexer 291 and a flip-flop 292. The multiplexer 291 selects and outputs either the write poison flag WPSN or the read poison flag RPSN based on the error check and scrub mode enable signal ECS-EN. The multiplexer 291 selects and outputs the write poison flag WPSN when the error check and scrub mode enable signal ECS-EN is at a low level according to deactivation of an ECS mode. The multiplexer 291 selects and outputs the read poison flag RPSN when the error check and scrub mode enable signal ECS-EN is at a high level according to activation of the ECS mode. The flip-flop 292 latches an output of the multiplexer 291 in response to the write command iWT and outputs the output of the multiplexer 291 as the poison pattern control signal PSNC.

FIG. 5 is a diagram illustrating a configuration of the data pattern conversion circuit 300, for example, as shown in FIG. 1.

Referring to FIG. 5, the data pattern conversion circuit 300 includes a plurality of multiplexers 310. Each of the plurality of multiplexers 310 selects and outputs one of bits of the delayed data DDT and the parity signal PRT and a ground voltage level based on the poison pattern control signal PSNC. The poison pattern control signal PSNC has the same logic value as each of the write poison flag WPSN and the read poison flag RPSN. A low level of the poison pattern control signal PSNC indicates that the delayed data DDT is not poisoned data, and a high level of the poison pattern control signal PSNC indicates that the delayed data DDT is poisoned data.

The plurality of multiplexers 310 outputs the delayed data DDT and the parity signal PRT to the second global line WGIO when the poison pattern control signal PSNC is at a low level. When the poison pattern control signal PSNC is at a high level, the plurality of multiplexers 310 selects a ground voltage level to convert the delayed data DDT and parity signal PRT into a poison pattern independent of original values and output the result to the second global line WGIO. Although FIG. 5 illustrates an example of a poison pattern where all bits have a value of 0, for a poison pattern where all bits have a value of 1, each of the plurality of multiplexers 310 is configured to select and output one of a power supply voltage level and bit of the delayed data DDT and the parity signal PRT based on the poison pattern control signal PSNC, where the “1” input of the plurality of multiplexers 310 is coupled to the power supply voltage.

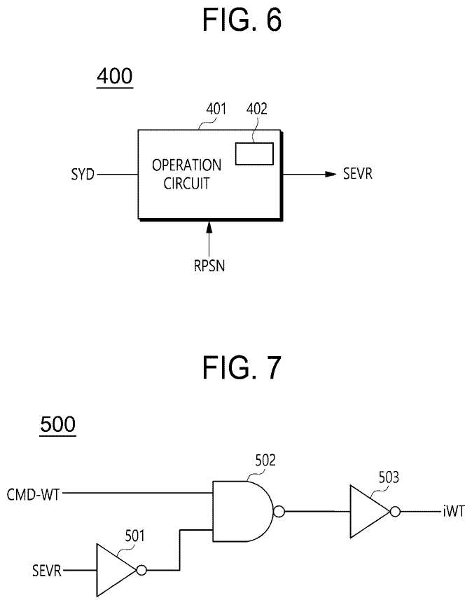

FIG. 6 is a diagram illustrating a configuration of the error severity determination circuit 400, for example, as shown in FIG. 1.

Referring to FIG. 6, the error severity determination circuit 400 includes an operation circuit 401 and a latch 402. The operation circuit 401 operates on the syndrome information SYD according to a predetermined operation logic to generate the error severity information SEVR when the read poison flag RPSN is deactivated at a low level. The operation circuit 401 adjusts the error severity information SEVR to a low level independent of the syndrome information SYD when the read poison flag RPSN is activated at a high level. The latch 402 stores the error severity information SEVR.

FIG. 7 is a diagram illustrating a configuration of the command control circuit 500, for example, as shown in FIG. 1.

Referring to FIG. 7, the command control circuit 500 includes a plurality of logic gates 501, 502, 503. A first logic gate 501 inverts and outputs the error severity information SEVR. A second logic gate 502 outputs a result from performing a NAND operation on the external write command CMD-WT and an output of the first logic gate 501. The third logic gate 503 outputs a signal that inverts an output of the second logic gate 502 as the write command iWT.

A normal write operation and a normal read operation of the error correction circuit 100 according to an embodiment of the present disclosure are described with reference to FIG. 1 to FIG. 7.

The normal write operation is described.

During the normal write operation, the data DT is input through the second global line WGIO, and separately, the write poison flag WPSN identifying whether the data DT is poisoned data is input.

The data DT is transmitted to the error processing circuit 220, and the delayed data DDT and the parity signal PRT are generated and transmitted to the data pattern conversion circuit 300.

When the data DT is not poisoned data, the write poison flag WPSN is at a low level. When the write poison flag WPSN is at a low level, the poison pattern control signal PSNC is also at a low level, the same as the write poison flag WPSN. Therefore, the data pattern conversion circuit 300 outputs the delayed data DDT and the parity signal PRT at their original values.

When the data DT is poisoned data, the write poison flag WPSN and the poison pattern control signal PSNC are at a high level. Therefore, the data pattern conversion circuit 300 converts and outputs the delayed data DDT and parity signal PRT into a poison pattern that is independent of original values. Because the poison pattern consists of all bits at either 0 or 1, the poison pattern is distinguished from normal data by the read poison flag RPSN generated by the poison detection circuit 280. Therefore, no additional information is utilized to distinguish the poisoned data from the normal data.

In an embodiment, when externally provided data is poisoned data during a normal write operation, the poisoned data is converted into a poison pattern and stored, allocation of additional memory region to store additional information to distinguish poisoned data from normal data is not needed. Therefore, the available memory capacity is not reduced and management of the poison function is facilitated.

The normal read operation is described.

During the normal read operation, the data DT is input through the first global line RGIO.

The data DT is transmitted to the error processing circuit 220, and the delayed data DDT, the parity signal PRT, the syndrome information SYD, and the error correction data CDT are generated accordingly. The error correction data CDT is output outside of the semiconductor device through the first global line RGIO.

The poison detection circuit 280 receives the data DT and generates the read poison flag RPSN. When the data DT is not poisoned data, the read poison flag RPSN is at a low level, and when the data DT is poisoned data, the read poison flag RPSN is at a high level.

When the read poison flag RPSN is at a low level, the error severity determination circuit 400 stores the error severity information SEVR as a low level corresponding to NE or CE or a high level corresponding to UE according to a result of operation on the syndrome information SYD.

When the read poison flag RPSN is at a high level, the error severity determination circuit 400 stores the error severity information SEVR at a low level corresponding to NE or CE regardless of the syndrome information SYD. The poison pattern consists of the values of all bits at 0 or the values of all bits at 1, and the error severity information SEVR is generated at a high level corresponding to UE when an operation is performed on the syndrome information SYD according to the poison pattern.

During the normal write operation, when the data DT is poisoned data, the data pattern conversion circuit 300 converts the delayed data DDT and the parity signal PRT into a poison pattern that is independent of original, or latest or unmodified, values of the delayed data DDT and the parity signal PRT. The operation specifications of the semiconductor device indicate that write operation is prohibited when the error severity information SEVR is at a high level corresponding to UE.

In an embodiment of the present disclosure, when the data DT during the normal read operation is poisoned data, the error severity information SEVR is stored at a low level corresponding to NE or CE to enable writing of poisoned data during an ECS write operation.

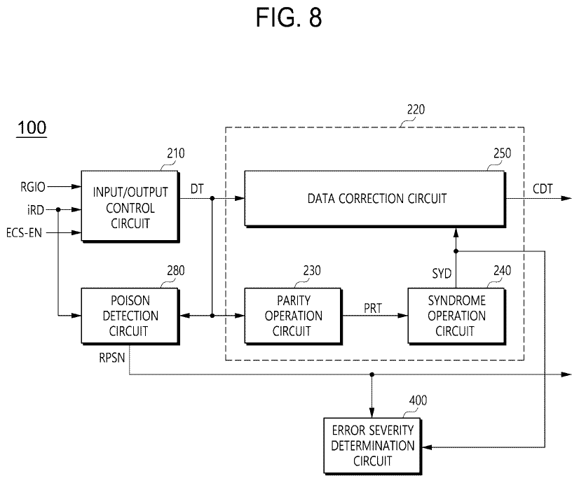

FIG. 8 is a diagram illustrating the error correction circuit 100 during an ECS read operation according to an embodiment of the present disclosure.

For ease of explanation, FIG. 8 illustrates only circuit configurations of FIG. 1 directly related to the ECS read operation. The ECS read operation of the error correction circuit 100 is described with reference to FIG. 8.

As the semiconductor device enters an ECS mode, the error check and scrub mode enable signal ECS-EN is activated.

The data DT transmitted on the first global line RGIO is transmitted to the error processing circuit 220, and the delayed data DDT, the parity signal PRT, the syndrome information SYD, and the error correction data CDT are generated. During the ECS mode, the error correction data CDT is stored in the global line latch circuit 110 and is not output outside the semiconductor device.

The poison detection circuit 280 outputs a result of detecting whether the data DT is poisoned as the read poison flag RPSN according to the read command iRD. The read poison flag RPSN is at a high level when the data DT is poisoned data and a low level when the data DT is not poisoned data.

When the read poison flag RPSN is at a low level, the error severity determination circuit 400 stores the error severity information SEVR at a low level corresponding to NE or CE or a high level corresponding to UE according to a result of operation on the syndrome information SYD.

When the read poison flag RPSN is at a high level, the error severity determination circuit 400 stores the error severity information SEVR at a low level corresponding to NE or CE regardless of the syndrome information SYD.

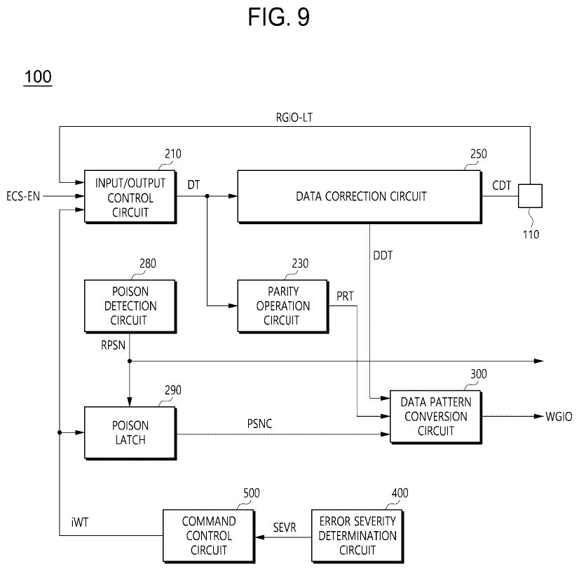

FIG. 9 is a diagram illustrating an ECS the error correction circuit 100 during an ECS write operation according to an embodiment of the present disclosure.

For ease of explanation, FIG. 9 illustrates only circuit configurations of FIG. 1 directly related to the ECS write operation. The ECS write operation of the error correction circuit 100 is described with reference to FIG. 9. The ECS write operation may be performed subsequent to the ECS read operation described with reference to FIG. 8.

The error severity determination circuit 400 stores the error severity information SEVR from a previous ECS read operation. The command control circuit 500 generates the write command iWT when the error severity information SEVR is at a low level and deactivates the write command iWT when the error severity information SEVR is at a high level. The error severity determination circuit 400 stores the error severity information SEVR at a low level when the data DT from the previous ECS operation is poisoned data.

When the error severity information SEVR is at a high level, the write command iWT is deactivated and the ECS write operation is not performed.

When the error severity information SEVR is at a low level, the write command iWT is generated at a predetermined time.

When the write command iWT is input while the error check and scrub mode enable signal ECS-EN is activated, the input/output control circuit 210 transmits a signal stored in the global line latch circuit 110 as the data DT to the data correction circuit 250 and the parity operation circuit 230.

The delayed data DDT and the parity signal PRT generated by the data correction circuit 250 and the parity operation circuit 230 are transmitted to the data pattern conversion circuit 300.

Because the ECS write operation is performed internally in the semiconductor device in this example, no write poison flag WPSN is provided from an external source. The poison latch 290 latches the read poison flag RPSN stored in the poison detection circuit 280 during a previous ECS read operation according to the write command iWT to generate the poison pattern control signal PSNC.

When the data DT is not poisoned data, the poison pattern control signal PSNC is at a low level, and the data pattern conversion circuit 300 outputs the delayed data DDT and parity signal PRT as their original values.

When the data DT is poisoned data, the poison pattern control signal PSNC is at a high level, and the data pattern conversion circuit 300 converts the delayed data DDT and the parity signal PRT into a poison pattern and writes the poison pattern to the memory region designated for the ECS read operation.

As described, an embodiment of the present disclosure can efficiently perform the ECS function with the poison function without allocating additional memory regions to store additional information to distinguish poisoned data from normal data.

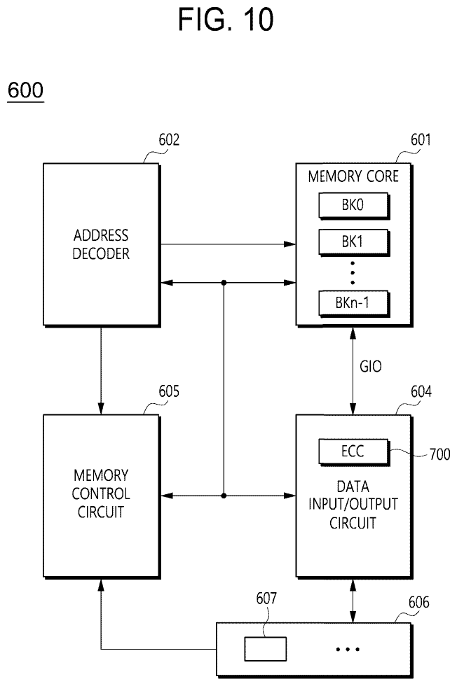

FIG. 10 is a diagram illustrating a semiconductor device 600 according to an embodiment of the present disclosure.

Referring to FIG. 10, the semiconductor device 600 includes a memory core 601, an address decoder 602, a data input/output circuit 604, a memory control circuit 605, an input/output pad circuit 606, and an error correction circuit ECC 700.

The memory core 601 includes a plurality of memory cells, and the plurality of memory cells includes at least one of volatile memory and non-volatile memory. The volatile memory may include static RAM (SRAM), dynamic RAM (DRAM), and synchronous DRAM (SDRAM), and the non-volatile memory may include read only memory (ROM), programmable ROM (PROM), electrically erase and programmable ROM (EEPROM), electrically programmable ROM (EPROM), flash memory, phase change RAM (PRAM), magnetic RAM (MRAM), resistive RAM (RRAM), and ferroelectric RAM (FRAM). The unit cells of the memory core 601 are divided into a plurality of memory regions, such as a plurality of memory banks BK0 through BKn−1.

The address decoder 602 is coupled with the memory control circuit 605 and the memory core 601. The address decoder 602 decodes an address signal provided by the memory control circuit 605 and accesses the memory core 601 in response to a decoding result.

The data input/output circuit 604 is coupled to the memory core 601 through a global line GIO. The data input/output circuit 604 exchanges data with an external system or the memory core 601. The global line GIO includes the first global line RGIO and the second global line WGIO described with reference to FIG. 1.

The memory control circuit 605 is coupled to the memory core 601, the address decoder 602, and the data input/output circuit 604. The memory control circuit 605 provides an address decoded through the address decoder 602 to the data input/output circuit 604. The memory control circuit 605 controls a test operation and data input and output related operations of the semiconductor device 600. The data input and output related operations may include a normal read operation, a normal write operation, an ECS read operation, an ECS write operation, and a poison function control operation.

The input/output pad circuit 606 includes a plurality of pads 607 for receiving commands, addresses, clock signals, and the write poison flag WPSN, inputting and outputting data, and outputting the read poison flag RPSN and the error severity information SEVR.

The error correction circuit 700 is configured similarly to the error correction circuit 100 described with reference to FIG. 1 to FIG. 7. The semiconductor device 600 described with reference to FIG. 10 includes an example of the error correction circuit 700 disposed in the data input/output circuit, although the error correction circuit 700 may be disposed in other regions coupled to the global line, such as in a region of the memory core 601.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. An error correction circuit comprising:
an error processing circuit configured to receive data, configured to generate delayed data, a parity signal, and syndrome information, and configured to output error correction data generated by correcting errors in the data according to the syndrome information;
a poison processing circuit configured to output one of a write poison flag and a read poison flag as a poison pattern control signal in accordance with a write command; and
a data pattern conversion circuit configured to convert the delayed data and the parity signal into a poison pattern according to the poison pattern control signal and output the poison pattern.

2. The error correction circuit of claim 1, wherein the error processing circuit comprises:
a parity operation circuit configured to generate the parity signal by performing an operation on the data;
a syndrome operation circuit configured to decode the parity signal to generate the syndrome information; and
a data correction circuit configured to delay the data by a first delay time period corresponding to a signal processing time period during which the parity signal and the syndrome information are generated.

3. The error correction circuit of claim 1, wherein the poison processing circuit comprises a poison latch configured to select one of the write poison flag and the read poison flag according to an error check and scrub mode enable signal, and configured to latch the selected signal according to the write command and output selected signal as the poison pattern control signal.

4. The error correction circuit of claim 1, wherein the poison processing circuit comprises a poison latch configured to latch the write poison flag in accordance with the write command and output write poison flag as the poison pattern control signal when an error check and scrub mode enable signal is deactivated.

5. The error correction circuit of claim 4, wherein the poison latch is configured to latch the read poison flag in accordance with the write command and output the read poison flag as the poison pattern control signal when the error check and scrub mode enable signal is activated.

6. The error correction circuit of claim 1, further comprising:
an error severity determination circuit configured to store a result of operation on the syndrome information according to a predetermined operation logic as error severity information when the read poison flag is deactivated; and
a command control circuit configured to activate the write command in accordance with the error severity information.

7. The error correction circuit of claim 1, further comprising:
a global line latch circuit coupled between the error processing circuit and a first global line and configured to latch the error correction data to generate a global line latch signal; and
an input/output control circuit configured to select one of a signal transmitted on the first global line, a signal transmitted on a second global line, and the global line latch signal based on an error check and scrub mode enable signal, a read command, and the write command, and configured to output the selected signal as the data,
wherein the first global line is used during a read operation, and the second global line is used during a write operation.

8. The error correction circuit of claim 7, wherein the global line latch circuit is configured to block the global line latch signal from output on the first global line when the error check and scrub mode enable signal is activated.

9. The error correction circuit of claim 7, wherein the input/output control circuit is configured to output the global line latch signal as the data when the write command is input while the error check and scrub mode enable signal is activated.

10. The error correction circuit of claim 1, wherein the poison pattern is a data pattern in which values of all bits of the data pattern are 0 or values of all bits of the data pattern are 1.

11. An error correction circuit comprising:
an error processing circuit configured to receive data, configured to generate a parity signal and syndrome information and configured to output error correction data generated by correcting errors in the data according to the syndrome information;
a poison processing circuit configured to output a result of detecting whether the data is poisoned as a read poison flag in accordance with a read command; and
an error severity determination circuit configured to store error severity information at a level that facilitates a write operation regardless of the syndrome information when the read poison flag is activated.

12. The error correction circuit of claim 11, wherein the poison processing circuit comprises:
an encoder configured to encode the data in a predetermined manner and configured to output whether a pattern of the data matches a predetermined poison pattern as a poison flag; and
a flip-flop configured to latch the poison flag according to the read command and output the latched signal as the read poison flag.

13. The error correction circuit of claim 11, further comprising:
a global line latch circuit coupled between the error processing circuit and a first global line and configured to latch the error correction data to generate a global line latch signal;
an input/output control circuit configured to select one of a signal transmitted on the first global line, a signal transmitted on a second global line, and the global line latch signal based on an error check and scrub mode enable signal, the read command, and a write command, and configured to output the selected signal as the data,
wherein the first global line is used during a read operation, and the second global line is used during a write operation.

14. The error correction circuit of claim 13, wherein the global line latch circuit is configured to block the global line latch signal from output on the first global line when the error check and scrub mode enable signal is activated.

15. An error correction circuit comprising:
an error processing circuit configured to receive data, configured to generate delayed data, a parity signal, and syndrome information, and configured to output error correction data generated by correcting errors in the data according to the syndrome information;
a poison processing circuit configured to output a result of detecting whether the data is poisoned as a read poison flag according to a read command and configured to output one of a write poison flag and the read poison flag as a poison pattern control signal according to a write command;
a data pattern conversion circuit configured to convert the delayed data and the parity signal into a poison pattern according to the poison pattern control signal and output the poison pattern;
an error severity determination circuit configured to store a result of operation on the syndrome information according to a predetermined operation logic as error severity information when the read poison flag is deactivated and configured to store the error severity information at a level that facilitates a write operation regardless of the syndrome information when the read poison flag is activated; and
a command control circuit configured to activate the write command in accordance with the error severity information.

16. The error correction circuit of claim 15, wherein the error processing circuit comprises:
a parity operation circuit configured to generate the parity signal by performing an operation on the data;
a syndrome operation circuit configured to decode the parity signal to generate the syndrome information; and
a data correction circuit configured to delay the data by a first delay time period corresponding to a signal processing time period during which the parity signal and the syndrome information are generated and configured to correct errors in the data in accordance with the syndrome information to generate the error correction data.

17. The error correction circuit of claim 15, wherein the poison processing circuit comprises:
a poison detection circuit configured to output the result of detecting whether the data is poisoned as the read poison flag according to the read command; and
a poison latch configured to select one of the write poison flag and the read poison flag according to an error check and scrub mode enable signal and configured to latch the selected signal according to the write command and output the latched selected signal as the poison pattern control signal.

18. The error correction circuit of claim 17, wherein the poison detection circuit comprises:
an encoder configured to encode the data in a predetermined manner and configured to output whether a pattern of the data matches a predetermined poison pattern as a poison flag; and
a flip-flop configured to latch the poison flag according to the read command and output the latched signal as the read poison flag.

19. The error correction circuit of claim 17, wherein the poison latch circuit comprises:
a multiplexer configured to select and output the write poison flag when the error check and scrub mode enable signal is deactivated and configured to select and output the read poison flag when the error check and scrub mode enable signal is activated; and
a flip-flop configured to latch an output of the multiplexer in response to the write command and configured to output the poison pattern control signal.

20. The error correction circuit of claim 15, further comprising:
a global line latch circuit coupled between the error processing circuit and a first global line and configured to latch the error correction data to generate a global line latch signal; and
an input/output control circuit configured to select one of a signal transmitted on the first global line, a signal transmitted on a second global line, and the global line latch signal based on an error check and scrub mode enable signal, the read command, and the write command, and configured to output the selected signal as the data,
wherein the first global line is used during a read operation, and the second global line is used during a write operation.

21. The error correction circuit of claim 20, wherein the global line latch circuit is configured to block the global line latch signal from output on the first global line when the error check and scrub mode enable signal is activated.

22. The error correction circuit of claim 20, wherein the input/output control circuit is configured to output the global line latch signal as the data when the write command is input while the error check and scrub mode enable signal is activated.

23. The error correction circuit of claim 15, wherein the poison pattern is a data pattern in which values of all bits of the data pattern are 0 or values of all bits of the data pattern are 1.

24. A semiconductor device comprising:
a memory region;
a first global line coupled with the memory region and configured to transmit data output from the memory region;
a second global line coupled with the memory region and configured to transmit data input from an external source to the memory region; and
an error correction circuit coupled with the first global line and the second global line, wherein the error correction circuit is configured to:
perform an error processing operation on first data transmitted on the first global line during an error check and scrub read operation to generate error correction data, and when the first data is poisoned data, activate a read poison flag and store error severity information corresponding to the first data at a level facilitating a write operation regardless of the error processing operation; and
receive a global line latch signal latched from the first global line during an error check and scrub write operation, and when the read poison flag is activated, convert the global line latch signal into a poison pattern and output the poison pattern on the second global line.

25. The semiconductor device of claim 24, wherein the semiconductor device is configured to block the error correction data from output outside the semiconductor device during the error check and scrub read operation.

26. The semiconductor device of claim 24, wherein the error correction circuit is configured to deactivate the read poison flag when the first data is not poisoned data during the error check and scrub read operation and configured to store the error severity information at a level prohibiting a write operation or at a level facilitating a write operation according to the error processing operation.

27. The semiconductor device of claim 24, wherein the error correction circuit is configured to receive second data and a write poison flag through the second global line during a normal write operation, and when the write poison flag is in an active state, configured to convert the second data into the poison pattern and output the poison pattern on the second global line.

28. The semiconductor device of claim 24, further comprising:
a global line latch circuit coupled to the first global line and configured to latch the error correction data to generate the global line latch signal; and
an input/output control circuit configured to select one signal from among a signal transmitted on the first global line, a signal transmitted on the second global line, and the global line latch signal, based on an error check and scrub mode enable signal that identifies activation of the error check and scrub read operation and the error check and scrub write operation, a read command, and a write command, and provide the selected signal to the error correction circuit.

29. The semiconductor device of claim 24, wherein the error correction circuit comprises:
an error processing circuit configured to receive the first data, configured to generate delayed data, a parity signal, and syndrome information, and configured to output the error correction data generated by correcting errors in the first data according to the syndrome information;
a poison processing circuit configured to output a result of detecting whether the first data is poisoned as the read poison flag according to a read command and configured to output one of a write poison flag and the read poison flag as a poison pattern control signal according to a write command;
a data pattern conversion circuit configured to convert the delayed data and the parity signal into a poison pattern according to the poison pattern control signal and output the poison pattern;
an error severity determination circuit configured to store a result of operation on the syndrome information according to a predetermined operation logic as the error severity information when the read poison flag is deactivated and configured to store the error severity information at a level that facilitates a write operation regardless of the syndrome information when the read poison flag is activated; and
a command control circuit configured to activate the write command in accordance with the error severity information.

30. The semiconductor device of claim 29, wherein the poison processing circuit comprises:
a poison detection circuit configured to output the result of detecting whether the first data is poisoned as the read poison flag according to the read command; and
a poison latch configured to select one of the write poison flag and the read poison flag according to an error check and scrub mode enable signal and configured to latch the selected signal according to the write command and output the latched selected signal as the poison pattern control signal.
